(19) United States
(12) Patent Application Publication
(10) Pub. No.: US 2022/0342309 A1
(43) Pub. Date: Oct. 27, 2022

(54) PHOTOSENSITIVE RESIN COMPOSITION AND DISPLAY DEVICE COMPRISING SAME

(71) Applicant: DONGJIN SEMICHEM CO., LTD., Incheon (KR)

(72) Inventors: Seung Han JEON, Hwaseong-si (KR); Hyoc Min YOUN, Hwaseong-si (KR); Jin Sun KIM, Hwaseong-si (KR); Jong Ho JEONG, Hwaseong-si (KR); Eui Soon KIM, Hwaseong-si (KR); Young Jun RYU, Hwaseong-si (KR); Chang Hwan AHN, Hwaseong-si (KR)

(21) Appl. No.: 17/724,888

(22) Filed: Apr. 20, 2022

(30) Foreign Application Priority Data
Apr. 20, 2021 (KR) 10-2021-0050937

(51) Int. Cl. G03F 7/075; C08G 77/20

(52) U.S. Cl. CPC G03F 7/0757; C08G 77/20

(57) ABSTRACT

Proposed is a photosensitive resin composition including a siloxane copolymer having both a thermosetting functional group and a photocurable functional group. The composition, according to this disclosure, is capable of both thermal curing and photo-curing and thus can form a stable cured film in a flexible display process where a low-temperature process of 150° C. or less is essential.

### CROSS REFERENCE TO RELATED APPLICATION

The present application claims priority from Korean Patent Application No.10-2021-0050937, filed on Apr. 20, 2021, which application is incorporated herein by reference in its entirety.

### BACKGROUND

### 1. Technical Field

The present disclosure relates to a photosensitive resin composition and a display device including the same. More particularly, the present disclosure relates to a photosensitive resin composition including both thermosetting functional groups and photocurable functional groups, thereby being curable at temperatures below and top of 150° C., and a display device including the same composition.

### 2. Description of the Related Art

The display industry has a high interest in flexible displays based on organic light emitting diodes (OLED) and quantum dot (QD) technologies. Following Korea, Chinese, Taiwanese, and Japanese companies are competitively attempting to expand their flexible display businesses.

Conventionally, due to the conventional use of glass substrates, the fields of application were limited due to the lack of flexibility and difficulty in bending (rigidity) of the display module. However, the use of resin substrates has given the flexibility to the substrate, enabling rollable and foldable designs of display devices. However, in the case of OLED displays, since the process at low temperature is inevitable, materials such as overcoats and passivation layers applied to the display must also be secured at low temperature.

It is known that a conventional siloxane composition can obtain a stable cured film only through a post-curing process under conditions of more than 150° C. and less than or equal to 300° C. Due to the post-curing conditions, it is difficult to apply the conventional siloxane composition to a flexible material-based device having reliability at a low temperature of 150° C. or less.

### SUMMARY

In order to solve the problems of the related art as described above, an objective of the present disclosure is to provide a photosensitive resin composition capable of stably forming a cured film at 150° C. or less.

Another objective of the present disclosure is to provide a display device including a cured film having excellent physical properties and formed on a flexible substrate required to undergo a low-temperature process of 150° C. or less.

A photosensitive resin composition according to one embodiment of the present disclosure to achieve the objectives includes: a siloxane copolymer including a thermosetting functional group and a photocurable functional group; a photoinitiator; and a solvent.

The thermosetting functional group may have a structure including any one or more selected from an epoxy group, oxetane, and tetrahydrofuran (THF).

The photocurable functional group may have a structure including an unsaturated photocurable functional group. The photocurable functional group may include, for example, at least one of a vinyl group and an acrylate group.

The photosensitive resin composition may include 0.1 to 30 parts by weight of the photoinitiator based on 100 parts by weight of the siloxane copolymer.

The photosensitive resin composition may include both a radical photoinitiator and an ion photoinitiator as a photoinitiator and may include 0.1 to 20 parts by weight of the radical photoinitiator and 0.1 to 10 parts by weight of the ion photoinitiator based on 100 parts by weight of the siloxane copolymer.

The siloxane copolymer may include repeating units represented by the following Formulae 1 to 2 and may include 1 mol % to 30 mol % of the repeating units represented by Formulae 1 and 2, respectively. In this specification, ‘formula’ is defined as ‘chemical formula’.

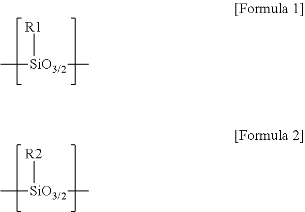

Where R1 is a thermosetting functional group, and R2 is a photocurable functional group.

In this case, the siloxane copolymer may further include a repeating unit represented by the following Formula 3, and the siloxane copolymer may include 50 mol % to 90 mol % of the repeating unit represented by the following Formula 3.

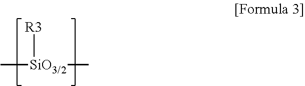

R3 is any one group selected among a hydroxyl group, a phenyl group, and an alkyl group having 1 to 10 carbon atoms.

The photosensitive resin composition may further include a multifunctional monomer having an ethylenically unsaturated bond, and the multifunctional monomer having an ethylenically unsaturated bond may be included in an amount of 1 to 50 parts by weight based on 100 parts by weight of the siloxane copolymer. In this case, the multifunctional monomer may have 2 to 20 functional groups.

In addition, the multifunctional monomer may include a 2 to 5 functional first monomer and a 6 or more functional second monomer together, and the molar ratio of the first monomer to the second monomer (first monomer: second monomer) may be 3:7 to 4:6.

A display device, according to another embodiment of the present disclosure, includes a cured body of the photosensitive resin composition. In this case, the cured body may be included in the display device as any one or more of a passivation film, a planarization film, and an interlayer insulating film.

The photosensitive resin composition, according to an embodiment of the present disclosure, can be cured at a temperature of 150° C. or less by reacting to both heat and light. In particular, the photosensitive resin composition, according to an embodiment of the present disclosure, has excellent pattern characteristics, adhesion, hardness, and chemical resistance in a flexible material substrate that requires a low-temperature process.

### DETAILED DESCRIPTION

The terms or words used in the present specification and claims should not be construed as being limited to their ordinary or dictionary meanings, and the inventor must be interpreted as meaning and concept consistent with the technical idea of the present disclosure on the basis of the principle that the concept of the term can be appropriately defined in order to explain his or her own disclosure in the best way.

Accordingly, the configurations shown in the embodiments and manufacturing examples described in this specification are only the most preferred embodiment of the present disclosure and do not represent all of the technical spirits of the present disclosure, so they cannot be replaced at the time of the present application. It should be understood that there may be various equivalents and variations that exist.

Hereinafter, embodiments of the present disclosure will be described in detail so that those of ordinary skilled in the art can easily carry out the present disclosure. However, the present disclosure may be embodied in several different forms and is not limited to the examples and examples described herein.

The photosensitive resin composition, according to an embodiment of the present disclosure, includes a siloxane copolymer, a photoinitiator, and a solvent capable of dissolving them. The siloxane copolymer includes both a thermosetting functional group and a photocurable functional group and thus has characteristics of being cured in both heat and light and thus may be cured at a lower temperature than a case of having only a conventional thermosetting functional group. Specifically, in the case of the conventional siloxane copolymer having only thermosetting functionalities, a stable cured film could be obtained only after a post-curing process of more than 150° C. and less than 300° C. However, in the case of the siloxane copolymer, according to the present disclosure, there is an additional photocurable functional group, and a stable cured film can be obtained even by a post-curing process of 150° C. or less. Therefore, the photosensitive resin composition is useful for flexible material-based devices that need to maintain a temperature of 150° C. or lower during the process.

The thermosetting functional group of the siloxane copolymer may specifically have a structure including at least one among an epoxy group, oxetane, and tetrahydrofuran (THF), and more specifically, may have a structure including an epoxy group. In order to form the siloxane copolymer including the thermosetting functional group, for example, at least one monomer among 3-glycidyloxypropyltrimethoxysilane, 3-glycidoxypropyltriethoxysilane, 3-glycidoxypropylmethyldiethoxysilane, 3-glycidoxypropylmethylmethoxysilane, 2-(3,4-epoxycyclohexyl)-ethyltrimethoxysilane, 2-(3,4-epoxycyclohexyl)-ethyltriethoxysilane, [Dimethyl(trimethylsiloxy)silyl]oxy-[3-[(3-ethyloxetan-3-yl)methoxy]propyl]-methyl-trimethylsilyloxysilane, 2-[(3-ethyloxetane-3-yl)methoxy]ethyl-methoxy-dimethylsilane, triethoxy-[1-[(3-ethyloxetan-3-yl)methoxymethyl]silane, triethoxy-[(3-ethyloxetan-3-yl)methoxymethyl]silane, (3-ethyloxetan-3-yl)methoxymethyl-trimethoxysilane, 2-[(3-ethyloxetan-3-yl)methoxy] ethyl-trimethoxysilane, diethoxy-[3-[(3-ethyloxetan-3-yl)methoxy]propyl]-methylsilane, 3-[(3-ethyloxetan-3-yl)methoxy]propyltrimethoxysilane, [(dimethyl(trimethylsiloxy)silyl)oxy-[3-[(3-ethyloxetan-3-yl)methoxy]propyl]-dimethylsilane, 1-{3-[(3-ethyloxetan-3-yl)methoxy]propyl}-1,1,3,3,3-pentamethyldisiloxane, triethoxy-[3-[(1-ethylcyclobutyl)methoxy]propyl]silane, 3-[(3-ethyloxetan-3-yl)methoxy]propyl-methyl-bis(trimethylsilyloxy)silane, 3-[(3-ethyloxetan-3-yl)methoxy]propyl-methoxy-dimethylsilane, [dimethyl(trimethylsilyloxy)silyl] oxy-[3-[(3-ethyloxetan-3-yl) methoxy] propyl]-methoxy-methylsilane, tri Butoxy-[3-[(3-ethyloxetan-3-yl)methoxy]propyl]silane, dibutoxy-[3-[(3-ethyloxetan-3-yl)methoxy]propyl]-methylsilane, 2-(triethylsiloxy)tetrahydrofuran, 3-(2,3-epoxypropoxy)propyl trimethoxysilane, 3-(2,3-epoxypropoxy-2-13C)propyl trimethoxysilane, and 3-glycidyloxypropyl triethoxysilane may be copolymerized to prepare a siloxane copolymer including thermosetting functional groups.

The photocurable functional group of the siloxane copolymer may be an unsaturated photocurable functional group having a carbon double bond or a triple bond, for example, a silane including a vinyl group or an acrylate group. In order to form the siloxane copolymer including the photocurable functional group, as specific examples, a siloxane copolymer including a photocurable functional group can be prepared by copolymerizing at least one monomer among chloro(dimethyl)vinylsilane, chloro-methyl-phenyl-vinylsilane, methylbis(trimethyl siloxy)vinylsilane, dimethyl(2-pyridyl)vinylsilane, vinyltris(2-methoxyethoxy)silane, vinyltriethoxysilane, vinyltrimethoxysilane, triacetoxy(vinyl)silane, dimethoxymethylvinylsilane, tris(trimethylsiloxy) (vinyl) silane, triphenyl(vinyl)silane, triethoxy(methyl)silane, triphenyl(vinyl)silane, triethoxy(octyl)silane, triethoxy(octadecyl)silane, trimethoxy(propyl)silane, isobutyl(triethoxy)silane, trimethoxy(7-octen-1-yl)silane, trimethoxy(2-phenylethyl)silane, and 3-methacryloxypropyl trimethoxysilane.

The photosensitive resin composition may include the photoinitiator in an amount of 0.1 to 30 parts by weight based on 100 parts by weight of the siloxane copolymer. When the amount of the photoinitiator is less than the above range, there may be a problem in that the residual film rate of the cured film is deteriorated due to the low sensitivity, or the chemical resistance of the cured film is deteriorated due to the low degree of curing. When the amount of the photoinitiator is larger than the above range, there may be a problem in that the developability of the photosensitive resin composition deteriorates or scum is generated in the cured product.

According to an embodiment of the present disclosure, the photosensitive resin composition may include both a radical photoinitiator and an ionic photoinitiator so that photocuring occurs effectively. The radical photoinitiator serves to advance the crosslinking reaction of the siloxane part containing the photocurable functional group of the siloxane copolymer, and the ionic photoinitiator promotes the crosslinking reaction of the epoxy group part included in the thermosetting functional group of the siloxane copolymer, thereby allowing the crosslinking reaction of the siloxane to occur sufficiently at low temperatures.

More specifically, the photosensitive resin composition is preferably included in an amount of 0.1 to 20 parts by weight of the radical photoinitiator and 0.1 to 10 parts by weight of the ionic photoinitiator based on 100 parts by weight of the siloxane copolymer. When the radical photoinitiator is included in an amount of less than 0.1 parts by weight, there may be a problem that the residual film rate of the cured film has deteriorated due to low sensitivity, and when the radical photoinitiator is included in more than 20 parts by weight, there may be a problem that the developability of the photosensitive resin composition has deteriorated, and the resolution of the display device including the cured film is lowered. In addition, when the amount of the ionic photoinitiator is included in less than 0.1 parts by weight, there may be a problem that the chemical resistance of the cured product deteriorates due to a low degree of curing, and when the amount of the ionic photoinitiator is included in excess of 20 parts by weight, there may be a problem that scum is formed in the cured product and the resolution of the display device using the cured product is lowered due to excessive curing.

The radical photoinitiator serves to advance the crosslinking reaction of the siloxane part containing the photocurable functional group of the siloxane copolymer, and specifically, a multifunctional acrylate oligomer may be photocured together with a siloxane part including a photocurable functional group of the siloxane copolymer. As the radical photoinitiator, for example, at least one radical photoinitiator among acetophenone-based compounds including 4-phenoxydichloroacetophenone, 4-t-butyl-dichloroacetophenone, diethoxyacetophenone, p-dimethylaminoacetophenone, 1-(4-isopropylphenyl)-2-hydroxy-2-methylpropane-1-one, 1-hydroxycyclohexylphenylketone, 2-methyl-1-[4-(methylthio)phenyl]-2-morpholinopropan-1-one, 2-benzyl-2-dimethylamino-1-(4-morpholinophenyl)-butan-1-one, and 2-(dimethylamino)-2-[(4-methylphenyl)methyl]-1-[4-(4-morpholinyl)phenyl]-1-butanone; benzoin-based compounds including benzoin, benzoin methyl ether, benzoin ethyl ether, benzoin isopropyl ether and benzyl dimethyl ketal; benzophenone-based compounds including benzophenone, benzoylbenzoic acid, methylbenzoylbenzoate, 4-phenylbenzophenone, hydroxybenzophenone, acrylated benzophenone, 4-benzoyl-4′-methyldiphenylsulfide, and 3,3′,4,4′-tetra(t-butylperoxycarbonyl)benzophenone; thioxanthone-based compounds including thioxanthone, 2-chlorothioxanthone, triazine-based chemicals including 2-methyldioxanthone, isopropylthioxanthone, 2,4-diisopropylthioxanthone, and 2,4-diethylthioxanthone; 2,4,6-trichloro-s-triazine, 2-phenyl-4,6-bis(trichloromethyl)-s-triazine, 2-(p-methoxyphenyl)-4,6-bis(Trichloromethyl)-s-triazine, 2-(p-tolyl)-4,6-bis(trichloromethyl)-s-triazine, 2-piperonyl-4,6-bis(trichloromethyl)-s-triazine, 2,4-bis(trichloromethyl)-6-styryl-s-triazine, 2-(naphtho-1-yl)-4,6-bis(trichloromethyl)-s-triazine, 2-(4-methoxy-naphtho-1-yl)-4,6-bis (trichloromethyl)-s-triazine, 2,4-trichloromethyl-(piperonyl)-6-triazine, 2,4-trichloromethyl(4′-methoxystyryl)-6-triazine; oxime ester-based compounds including 2-(O-benzoyloxime)-1-[4-(phenylthio)phenyl]-1,2-octanedione, 1-(O-acetyloxime)-1-[9-ethyl-6-(2-methyl Benzoyl)-9H-carbazol-3-yl]-ethanone, O-ethoxycarbonyl-α-oxyamino-1-phenylpropan-1-one, 1,2-octanedione, 2-dimethylamino-2-(4-Methylbenzyl)-1-(4-morpholin-4-yl-phenyl)-butan-1-one, 1-(4-phenylsulfanylphenyl)-butane-1,2-dione-2-Oxime-O-benzoate, 1-(4-phenylsulfanylphenyl)-octane-1,2-dione-2-oxime-O-benzoate, 1-(4-phenylsulfanylphenyl)-octane-1-Onoxime-O-acetate, 1-(4-phenylsulfanylphenyl)-butan-1-oneoxime-O-acetate, 2-(O-benzoyloxime)-1-[4-(phenylthio)p-methylphenyl]-1,2-octanedione, 2-(O-benzoyloxime)-1-[4-(phenylthio)phenyl]-1,2-phenyldione, 2-(O-acetyloxime)-1-[4-(phenylthio)phenyl]-1,2-octanedione, 2-(O-acetyloxime)-1-[4-(phenylthio)phenyl]-1,2-phenyldione, 2-(O-acetyloxime)-1-[4-(phenylthio)phenyl]-1,2-methyldione and O-(acetyl)-N-(1-phenyl-2-oxo-2-(4′-methoxy-naphthyl)ethylidene)hydroxylamine; phosphine-based compounds including bis(2,4,6-trimethylbenzoyl)phenylphosphine oxide and 2,4,6-trimethylbenzoyl-diphenyl-phosphine oxide; imidazole-based compounds including 2,2′-bis(o-chlorophenyl)-4,5,4′,5′-tetraphenyl-1,2′-biimidazole, 2,2′-bis(o-methoxyphenyl)-4,4′,5,5′-tetraphenylbiimidazole, and 2,2′-bis(o-methoxyphenyl)-4,4′,5,5′-tetra(p-methylphenyl)biimidazole; quinone-based compounds including 9,10-phenanthrenequinone, camphorquinone and ethylanthraquinone; borate-based compounds; carbazole-based compounds; and titanocene-based compounds may be used.

The ion photoinitiator enables photocuring through an epoxy group included in the thermosetting functional group of the siloxane copolymer, thereby promoting the siloxane copolymer to be cured at a lower temperature. The ionic photoinitiator may use at least one of cationic photoinitiator and an anionic photoinitiator, for example, the cationic photoinitiator includes onium salt-based compounds such as sulfonium salt-based, iodonium salt-based, phosphonium salt-based, diazonium salt-based, pyridinium salt-based, benzothiazolium salt-based, sulfoxonium salt-based, and ferrocene-based compounds. In addition, the cationic photoinitiator further includes nitrobenzylsulfonates, alkyl or allyl-N-sulfonyloxyimides, halogenated alkylsulfonic acid esters, oxime sulfonates, etc., but are not limited thereto. More specifically, the cationic photoinitiator includes tetrabutylammonium tetrafluoroborate, tetrabutylammonium hexafluorophosphate, tetrabutylammonium hydrogen sulfate, tetraethylammonium tetrafluoroborate, tetraethylammonium, p-toluenesulfonate, N,N-dimethyl-N-benzylanilinium hexafluoroantimonate, N,N-dimethyl-N-benzylanilinium tetrafluoroborate, N,N-dimethyl-N-benzylpyridinium hexafluoroantimonate, N,N-dimethyl-N-benzyltrifluoromethane sulfonic acid, N,N-dimethyl-N-(4-methoxybenzyl)pyridinium hexafluoroantimonate, N,N-dimethyl-N-(4-methoxybenzyl)toluidinium hexafluoroantimonate, ethyltriphenylphosphonium hexafluoroantimonate, tetrabutylphosphonium hexafluoroantimonate, triphenylsulfonium tetrafluoroborate, triphenylsulfonium hexafluoroantimonate, triphenylsulfonium hexafluoroarsenate, tri(4-methoxyphenyl)sulfonium hexafluoroarsenate, diphenyl(4-phenylthiophenyl)sulfonium hexafluoroarsenate, diphenyl iodonium hexafluoroarsenate, di-4-chlorophenyl iodonium hexafluoroarsenate, di-4-bromphenyl iodonium hexafluoroarsenate, phenyl (4-methoxyphenyl) iodonium arsenic hexafluoride, diphenyl iodonium hexafluorophosphate, di-4-chlorophenyl iodonium hexafluorophosphate, di-4-bromphenyl iodonium hexafluorophosphate, phenyl (4-methoxyphenyl)iodonium hexafluorophosphate, 4-methylphenyl (4-(2-methylpropylphenyl))iodonium hexafluorophosphate, di-4-tetraphenyliodonium hexafluorophosphate, diphenyliodonium hexafluorophosphate, di-4-tetraphenyliodonium hexafluoroantimonate, diphenyliodonium hexafluoroantimonate , 4-methylphenyl(4-(2-methylpropylphenyl))iodonium tetrafluoroarsenate, and the like, but are not limited thereto.

As the anionic photoinitiator, at least one material of benzoincarbamate, dimethylbenzyloxycarbamoylamine, o-acyloxime, o-nitrobenzoincarbamate, formanilide derivatives, and α-ammoniumacetophenone may be used.

The siloxane copolymer may specifically include repeating units represented by the following Formulae 1 to 2, in which R1 of the following Formula 1 refers to a thermosetting functional group, and R2 of the following Formula 2 refers to a photocurable functional group. Therefore, due to the R1 and R2 functional groups of the siloxane copolymer, a photosensitive resin composition having dual curing properties capable of both thermal curing and photocuring may be obtained.

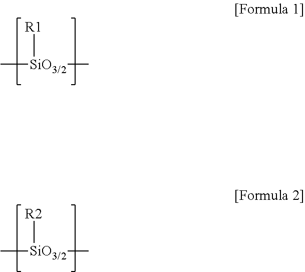

Specifically, the siloxane copolymer preferably contains 1 to 30 parts by weight of the repeating unit represented by Formula 1, more specifically 1 to 15 parts by weight. When the repeating unit represented by Formula 1 is included in an amount of less than 1 part by weight, an adhesive force of the photosensitive resin composition may be decreased, and a residue of the cured film may be observed, and when it contains more than 30 parts by weight, there may be a problem that synthetic reproducibility of the photosensitive resin composition may occur. In addition, the siloxane copolymer preferably contains 1 to 30 parts by weight of the repeating unit represented by Formula 2, more specifically 5 to 20 parts by weight. When the repeating unit represented by Formula 2 is included in an amount of less than 1 part by weight, the chemical resistance and residual film ratio of the cured film may have deteriorated, and when included in more than 30 parts by weight, a problem in which the synthetic reproducibility of the photosensitive resin composition and residues are observed in the photosensitive resin composition may occur.

The siloxane copolymer preferably has average molecular weight (Mw) of 3,000 to 30,000 g/mol which is a polystyrene-converted weight. When the polystyrene-converted weight average molecular weight of the siloxane copolymer is less than 3,000 g/mol, when the cured film is used as an organic insulating film, developability and residual film rate may be degraded, or physical properties such as pattern formation and heat resistance may be degraded, and when the polystyrene-converted weight average molecular weight of the siloxane copolymer exceeds 30,000 g/mol when the cured film is used as an interlayer insulating film, a problem in which the pattern shape has deteriorated may occur.

The siloxane copolymer may have a structure including repeating units represented by the following Formulae 1 to 3 by the polymerization reaction.

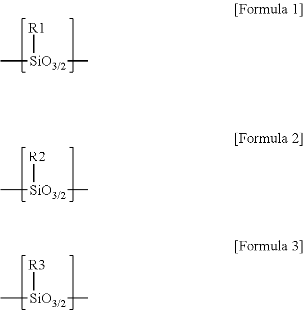

R1 is a thermosetting functional group, R2 is a photocurable functional group, and R3 is any one group selected from a hydroxyl group, a phenyl group, and an alkyl group having 1 to 10 carbon atoms.

Specifically, the siloxane copolymer, including Formulae 1 to 3 may have a hydroxyl group (—OH) at the end of the main chain. This is because the composition can be developed only when a hydroxyl group (—OH) is present at the end of the main chain of the siloxane copolymer.

In the case of the siloxane copolymer including the repeating unit of Formula 3, the repeating unit represented by Formula 1 is included in an amount of 1 to 30 parts by weight, more specifically, 1 to 15 parts by weight and the repeating unit represented by Formula 2 is included in an amount of to 30 parts by weight, more specifically 5 to 20 parts by weight, and the repeating unit represented by Formula 3 is preferably included in an amount of 50 to 90 parts by weight. As mentioned above with respect to Formulae 1 and 2, in the case of Formula 3, when the repeating unit is included in an amount of less than 50 parts by weight, a problem of poor synthesis reproducibility of the photosensitive resin composition may occur, and when the repeating unit is included in an amount of excess of 90 parts by weight, chemical resistance may be degraded, a residue of a pattern may be observed, and adhesive force may be degraded when used in the photosensitive resin composition.

The photosensitive resin composition may further include a multifunctional monomer or oligomer having an ethylenically unsaturated bond together with the composition.

The multifunctional monomer or oligomer is preferably included in an amount of 1 to 50 parts by weight based on 100 parts by weight of the siloxane copolymer. When the multifunctional monomer or oligomer is included in an amount of less than 1 part by weight, a problem in which the residual film rate of the cured film is deteriorated due to low sensitivity may occur, and when the multifunctional monomer or oligomer is included in an amount of more than 50 parts by weight, a problem in which the developability of the photosensitive resin composition has deteriorated, and then the resolution of the display device using the cured product is lowered.

Specifically, the multifunctional monomer or oligomer has 2 to 20 functional groups, and for example, the multifunctional oligomer may use at least one of an oligomer among an aliphatic urethane acrylate oligomer, an aromatic urethane acrylate oligomer, an epoxy acrylate oligomer, an epoxy methacrylate oligomer, a polyester acrylate oligomer, a silicone acrylate oligomer, a melamine acrylate oligomer, and dendritic acrylate oligomers.

According to an embodiment of the present disclosure, the multifunctional monomer may include only one kind of multifunctional monomer, but according to another embodiment of the present disclosure, the multifunctional monomer may include a first monomer having 2 to 5 functional groups and a second monomer having functional groups of 6 or more together in the multifunctional monomer is good to improve the residual film rate and developability.

More specifically, the molar ratio of the first monomer to the second monomer (first monomer: second monomer) is preferably 3:7 to 4:6. In the molar ratio range, the residual film ratio, pattern residue, and profile characteristics may be particularly excellent.

Specifically, the solvent included in the photosensitive resin composition may use a solvent having a boiling point of less than 150° C. In this way, the siloxane copolymer may be cured at less than 150° C., and this is to minimize residual solvent in a low-temperature process and increase chemical resistance.

The solvent may be used at least one solvent among, for example, methyl-2-hydroxyisobutyrate, ethyleneglycol methylether acetate, 2-methoxy-1-methylethyl ester, propylene acetate), ethyl propionate, ethyl pyruvate, 1-methoxy-2-propanol, dibutyl ether, ethylene glycol monomethyl ether, ethylene glycol dimethyl ether, propylene glycol dimethyl ether, tetrahydrofuran, methanol, ethanol, and isopropyl alcohol.

The photosensitive resin composition is preferably used by filtration with a 0.1 to 0.2 μm Millipore filter such that the solid content is 10 to 50% by weight, more specifically 15 to 40% by weight, based on the total solvent-containing solution. When the solid content is an amount of less than 10% by weight, the coating thickness becomes thin, and a problem in which the coating flatness has deteriorated may occur, and when the solid content is an amount of more than 50% by weight, the coating thickness becomes thick, the coating equipment is overworked during coating, and particularly, a problem in which the residual solvent may increase may occur.

The siloxane copolymer may include at least one of alkoxy or alkyl silane as a monomer. For example, one or more of tetramethoxysilane and tetraethoxysilane may be used as a tetrafunctional alkoxysilane. As the trifunctional alkoxy silane, one or more compounds of triethoxysilane, methyltriethoxysilane, ethyltriethoxysilane, aminopropyl triethoxysilane, 3-mercaptopropyl triethoxysilane, 3-isocyanatopropyl triethoxysilane, 3-chloropropyl triethoxysilane, 4-chloropropyl triethoxysilane, chloromethyl triethoxysilane, 3-bis (2-hydroethyl)amino propyl triethoxysilane, 1,2-bis(triethoxysilyl)ethane, (2-cyanoethyl)triethoxysilane, 3,3′-tetrathiobis(propyl-triethoxysilane), (1-naphthyl)triethoxysilane, dodecyltriethoxysilane, phenyltriethoxysilane, (3-aminopropyl)trimethoxysilane, (3-chloropropyl)trimethoxysilane, (3-glycytyloxypropyl)trimethoxysilane, (3-mercappropyl)trimethoxysilane, (N,N-dimethylaminopropyl)trimethoxysilane, [3-(2-aminoethylamino)propyl] trimethoxysilane, trimethoxysilane, (3-bromopropyl)trimethoxysilane, (3-iodopropyl)trimethoxysilane, (chloromethyl)trimethoxysilane, 2,4,4-trimethoxypentyl trimethoxysilane, [3-(diethylamino)propyl] trimethoxysilane, bis(3-methylamino)propyl) trimethoxysilane, 1,2,bis(trimethoxysilane) ethane, (3-acryloyloxypropyl) trimethoxysilane, [3-(methylacryloyloxy]propyl) trimethoxysilane, (3-anilinopropyl) trimethoxysilane, trimethoxy[3-(methylamino)propyl]silane, trimethoxy(2-phenylethyl)silane, triethoxy(3,3,3-trifluoropropyl)silane, trimethoxy(7-octen-1-yl)silane, trimethoxy[2-(7-octabicyclo[4.1.0]hepta-3-yl)ethyl]silane, methyl-tripropoxy silane, tripentyloxysilane, phenyltrimethoxysilane may be used. AS a bifunctional alkoxysilane, one or more of (chloromethyl)methyl diethoxysilane, 3-aminopropyl(diethoxy)methylsilane, diethoxy(methyl)phenylsilane, bis(1-naphthyl)diethoxysilane, bis(methylthio)diethoxysilane, chloromethyl(methyl)dimethoxysilane, and dimethoxy-methyl (3,3,3-trifluoropropyl)silane may be used. Particularly, tetrafunctional silane is highly copolymerizable and soluble in aqueous alkali solution, which is a developer, so synthesizing tetrafunctional silane by appropriately mixing it with 2,3 functional silane is recommended.

A copolymer may be formed by polymerizing the silane containing the thermosetting functional group and the silane containing the photocurable functional group together with one or more silanes of alkoxysilane and alkylsilane in the presence of an acid catalyst, specifically, unreacted monomers can be removed through a vacuum drying process.

A melamine crosslinking agent may be further included to improve heat resistance, chemical resistance, and adhesion of the photosensitive resin composition. As the melamine crosslinking agent, for example, a condensation product of urea and formaldehyde, a condensation product of melamine and formaldehyde, or methylolurea alkylethers or methylolmelamine alkylethers obtained from alcohol may be used. More specifically, as the condensation product of urea and formaldehyde, monomethylolurea, dimethylolurea, or the like may be used. As the condensation product of melamine and formaldehyde, hexamethylolmelamine may be used, and in addition, a partial condensation product of melamine and formaldehyde may be used. In addition, the methylol urea alkyl ethers are obtained by reacting alcohols with a part or all of a methylol group with a condensed product of urea and formaldehyde, and as specific example thereof, monomethyl urea methyl ether, dimethyl urea methyl ether, and the like may be used. The methylol-melamine alkyl ether is obtained by reacting alcohols with a part or all of a methylol group with a condensed product of melamine and formaldehyde, and as a specific example thereof, hexamethylol-melamine hexamethyl ether, hexamethylol-melaine hexabutyl ether, and the like may be used. In addition, a compound having a structure in which a hydrogen atom of an amino group of melamine is substituted with a hydroxy methyl group and a methoxy methyl group, a compound having a structure in which a hydrogen atom of an amino group of melamine is substituted with a butoxy methyl group and a methoxy methyl group may be used, especially methylolmelamine alkylethers may be used.

The melamine crosslinking agent is preferably used in an amount of 0.1 to 20 parts by weight based on 100 parts by weight of the siloxane copolymer. When the melamine crosslinking agent is used in an amount of less than 0.1 parts by weight, the improvement of heat resistance, chemical resistance, and adhesive strength of the photosensitive resin composition may be insignificant, and when the melamine crosslinking agent is used in an amount of more than 20 parts by weight, scum may occur in the cured film, and the image quality of a display device using the cured film may be degraded.

The photosensitive resin composition may further include a silane coupling agent to improve adhesion to the substrate. As the silane coupling agent, for example, one or more of the compounds among (3-glycidoxypropyl)trimethoxysilane, (3-glycidoxypropyl)triethoxysilane, (3-glycidoxypropyl)methyldimethoxysilane, (3-glycidoxypropyl)methyldiethoxysilane, (3-glycidoxypropyl)dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane, 3-triethoxysilly-N-(1,3 dimethyl-butylidene)propylamine, N-2(aminoethyl)3-aminopropyltrimethoxysilane, N-2(aminoethyl)3-aminopropyltriethoxysilane, N-2(aminoethyl)3-aminopropylmethyldimethoxysilane, N-phenyl-3-aminopropyltrimethoxysilane, and (3-isocyanatepropyl)triethoxysilane may be used.

The silane coupling agent may be included in an amount of 0.1 to 20 parts by weight based on 100 parts by weight of the siloxane copolymer. When the silane coupling agent is included in an amount of less than 0.1 parts by weight, a problem of poor adhesion between the cured film and the substrate may occur. When the silane coupling agent is included in an amount of more than 20 parts by weight, a problem in which scum is generated in the cured film may occur.

The photosensitive resin composition may specifically be a negative photosensitive resin composition and may be used in the photosensitive resin process.

The cured product, according to an embodiment of the present disclosure, is prepared by curing the photosensitive resin composition and more specifically, may be in the form of a film. The cured film may be specifically prepared by curing at a low temperature of 150° C. or less. Since the cured film is cured at 150° C. or less, the cured film can be formed on a flexible display device substrate using a polymer substrate instead of a glass substrate.

A display device, according to an embodiment of the present disclosure, includes a cured product of the photosensitive resin composition and may be, for example, a display device using the photosensitive resin composition as a cured film. In particular, the display device may be a flexible display device that requires a low-temperature process of 150° C. or less, and among the flexible display devices, for example, an OLED display device, and the photosensitive resin composition may be used as a material of an overcoat or passivation layer in the OLED device.

The cured body may be included in the display device as, for example, any one or more of a passivation film, a planarization film, and an interlayer insulating film.

Hereinafter, preferred embodiments are presented to help understand the present disclosure, but the following embodiments only illustrate the present disclosure, and the scope of the present disclosure is not limited to the following embodiments.

### SYNTHESIS EXAMPLE

### Preparation of Siloxane Copolymer

### Synthesis Example 1

A mixed solution of 1 part by weight of vinyltrimethoxysilane, 10 parts by weight of 3-glycidyloxypropyl trimethoxysilane, 35 parts by weight of phenyltrimethoxysilane, and 54 parts by weight of tetraethoxysilane was put in a flask provided with a cooler and a stirrer. After the liquid composition was sufficiently mixed at 600 rpm in a mixing container, 350 parts by weight of oxalic acid solution in which oxalic acid was added to purified water by making 0.01 wt % aqueous solution is added to prepare a polymerization mixture solution. The temperature of the polymerization mixture solution is slowly raised to 70° C., maintained at the temperature for 48 hours, cooled to room temperature, and twice the amount of propyleneglycolmonoethylacetate is added to the polymerization mixture solution. After mixing, the siloxane-based copolymer was prepared by vacuum drying at 30° C. or less to remove unreacted monomers and solvents of alcohols generated during the reaction.

### Synthesis Example 2

A siloxane copolymer was synthesized in the same manner as in Synthesis Example 1, except that a mixed solution of 4 parts by weight of vinyl trimethoxysilane, 10 parts by weight of 3-glycidyloxypropyl trimethoxysilane, 35 parts by weight of phenyltrimethoxysilane, and 51 parts by weight of tetraethoxysilane was added.

### Synthesis Example 3

A siloxane copolymer was synthesized in the same manner as in Synthesis Example 1, except that a mixed solution of 5 parts by weight of vinyl trimethoxysilane, 10 parts by weight of 3-glycidyloxypropyl trimethoxysilane, 35 parts by weight of phenyltrimethoxysilane, and 50 parts by weight of tetraethoxysilane was added.

### Synthesis Example 4

A siloxane copolymer was synthesized in the same manner as in Synthesis Example 1, except that a mixed solution of 10 parts by weight of vinyl trimethoxysilane, 10 parts by weight of 3-glycidyloxypropyl trimethoxysilane, 35 parts by weight of phenyltrimethoxysilane, and 45 parts by weight of tetraethoxysilane was added.

### Synthesis Example 5

A siloxane copolymer was synthesized in the same manner as in Synthesis Example 1, except that a mixed solution of 15 parts by weight of vinyl trimethoxysilane, 10 parts by weight of 3-glycidyloxypropyl trimethoxysilane, 35 parts by weight of phenyltrimethoxysilane, and 40 parts by weight of tetraethoxysilane was added.

### Synthesis Example 6

A siloxane copolymer was synthesized in the same manner as in Synthesis Example 1, except that a mixed solution of 20 parts by weight of vinyl trimethoxysilane, 10 parts by weight of 3-glycidyloxypropyl trimethoxysilane, 35 parts by weight of phenyltrimethoxysilane, and 35 parts by weight of tetraethoxysilane was added.

### Synthesis Example 7

A siloxane copolymer was synthesized in the same manner as in Synthesis Example 1, except that a mixed solution of 21 parts by weight of vinyl trimethoxysilane, 10 parts by weight of 3-glycidyloxypropyl trimethoxysilane, 35 parts by weight of phenyltrimethoxysilane, and 34 parts by weight of tetraethoxysilane was added.

### Synthesis Example 8

A siloxane copolymer was synthesized in the same manner as in Synthesis Example 1, except that a mixed solution of 30 parts by weight of vinyl trimethoxysilane, 10 parts by weight of 3-glycidyloxypropyl trimethoxysilane, 35 parts by weight of phenyltrimethoxysilane, and 25 parts by weight of tetraethoxysilane was added.

### Synthesis Example 9

A siloxane copolymer was synthesized in the same manner as in Synthesis Example 1, except that a mixed solution of 1 part by weight of 3-methylacryloxypropyl trimethoxysilane, 10 parts by weight of 3-glycidyloxypropyl trimethoxysilane, 35 parts by weight of phenyltrimethoxysilane, and 54 parts by weight of tetraethoxysilane was added.

### Synthesis Example 10

A siloxane copolymer was synthesized in the same manner as in Synthesis Example 1, except that the mixed solution of 4 parts by weight of 3-methylacryloxypropyl trimethoxysilane, 10 parts by weight of 3-glycidyloxypropyl trimethoxysilane, 35 parts by weight of phenyltrimethoxysilane, and 51 parts by weight of tetraethoxysilane was added.

### Synthesis Example 11

A siloxane copolymer was synthesized in the same manner as in Synthesis Example 1, except that a mixed solution of 4 parts by weight of 3-methylacryloxypropyl trimethoxysilane, 10 parts by weight of 3-glycidyloxypropyl trimethoxysilane, 35 parts by weight of phenyltrimethoxysilane, and 51 parts by weight of tetraethoxysilane was added.

### Synthesis Example 12

A siloxane copolymer was synthesized in the same manner as in Synthesis Example 1, except that a mixed solution of 10 parts by weight of 3-methylacryloxypropyl trimethoxysilane, 10 parts by weight of 3-glycidyloxypropyl trimethoxysilane, 35 parts by weight of phenyltrimethoxysilane, and 45 parts by weight of tetraethoxysilane was added.

### Synthesis Example 13

A siloxane copolymer was synthesized in the same manner as in Synthesis Example 1, except that a mixed solution of 15 parts by weight of 3-methylacryloxypropyl trimethoxysilane, 10 parts by weight of 3-glycidyloxypropyl trimethoxysilane, 35 parts by weight of phenyltrimethoxysilane, and 40 parts by weight of tetraethoxysilane was added.

### Synthesis Example 14

A siloxane copolymer was synthesized in the same manner as in Synthesis Example 1, except that a mixed solution of 20 parts by weight of 3-methylacryloxypropyl trimethoxysilane, 10 parts by weight of 3-glycidyloxypropyl trimethoxysilane, 35 parts by weight of phenyltrimethoxysilane, and 35 parts by weight of tetraethoxysilane was added.

### Synthesis Example 15

A siloxane copolymer was synthesized in the same manner as in Synthesis Example 1, except that a mixed solution of 21 parts by weight of 3-methylacryloxypropyl trimethoxysilane, 10 parts by weight of 3-glycidyloxypropyl trimethoxysilane, 35 parts by weight of phenyltrimethoxysilane, and 34 parts by weight of tetraethoxysilane was added.

### Synthesis Example 16

A siloxane copolymer was synthesized in the same manner as in Synthesis Example 1, except that a mixed solution of 30 parts by weight of 3-methylacryloxypropyl trimethoxysilane, 10 parts by weight of 3-glycidyloxypropyl trimethoxysilane, 35 parts by weight of phenyltrimethoxysilane, and 25 parts by weight of tetraethoxysilane was added.

### Synthesis Example 17

A siloxane copolymer was synthesized in the same manner as in Synthesis Example 1, except that a mixed solution of 15 parts by weight of vinyl trimethoxysilane, 1 parts by weight of 3-glycidyloxypropyl trimethoxysilane, 35 parts by weight of phenyltrimethoxysilane, and 49 parts by weight of tetraethoxysilane was added.

### Synthesis Example 18

A siloxane copolymer was synthesized in the same manner as in Synthesis Example 1, except that a mixed solution of 15 parts by weight of vinyl trimethoxysilane, 5 parts by weight of 3-glycidyloxypropyl trimethoxysilane, 35 parts by weight of phenyltrimethoxysilane, and 45 parts by weight of tetraethoxysilane was added.

### Synthesis Example 19

A siloxane copolymer was synthesized in the same manner as in Synthesis Example 1, except that a mixed solution of 15 parts by weight of vinyl trimethoxysilane, 15 parts by weight of 3-glycidyloxypropyl trimethoxysilane, 35 parts by weight of phenyltrimethoxysilane, and 35 parts by weight of tetraethoxysilane was added.

### Synthesis Example 20

A siloxane copolymer was synthesized in the same manner as in Synthesis Example 1, except that a mixed solution of 15 parts by weight of vinyl trimethoxysilane, 16 parts by weight of 3-glycidyloxypropyl trimethoxysilane, 35 parts by weight of phenyltrimethoxysilane, and 34 parts by weight of tetraethoxysilane was added.

### Synthesis Example 20

A siloxane copolymer was synthesized in the same manner as in Synthesis Example 1, except that a mixed solution of 15 parts by weight of vinyl trimethoxysilane, 20 parts by weight of 3-glycidyloxypropyl trimethoxysilane, 35 parts by weight of phenyltrimethoxysilane, and 30 parts by weight of tetraethoxysilane was added.

### Synthesis Example 21

A siloxane copolymer was synthesized in the same manner as in Synthesis Example 1, except that a mixed solution of 15 parts by weight of vinyl trimethoxysilane, 20 parts by weight of 3-glycidyloxypropyl trimethoxysilane, 35 parts by weight of phenyltrimethoxysilane, and 30 parts by weight of tetraethoxysilane was added.

### Synthesis Example 22

A siloxane copolymer was synthesized in the same manner as in Synthesis Example 1, except that a mixed solution of 15 parts by weight of vinyl trimethoxysilane, 30 parts by weight of 3-glycidyloxypropyl trimethoxysilane, 35 parts by weight of phenyltrimethoxysilane, and 20 parts by weight of tetraethoxysilane was added.

### Synthesis Example 23

A siloxane copolymer was synthesized in the same manner as in Synthesis Example 1, except that a mixed solution of 15 parts by weight of vinyl trimethoxysilane, 1 part by weight of 2-(3,4-epoxycyclohexyl)-ethyltrimethoxysilane, 35 parts by weight of phenyltrimethoxysilane, and 49 parts by weight of tetraethoxysilane was added.

### Synthesis Example 24

A siloxane copolymer was synthesized in the same manner as in Synthesis Example 1, except that a mixed solution of 15 parts by weight of vinyl trimethoxysilane, 5 parts by weight of 2-(3,4-epoxycyclohexyl)-ethyltrimethoxysilane, 35 parts by weight of phenyltrimethoxysilane, and 45 parts by weight of tetraethoxysilane was added.

### Synthesis Example 25

A siloxane copolymer was synthesized in the same manner as in Synthesis Example 1, except that a mixed solution of 15 parts by weight of vinyl trimethoxysilane, 10 parts by weight of 2-(3,4-epoxycyclohexyl)-ethyltrimethoxysilane, 35 parts by weight of phenyltrimethoxysilane, and 40 parts by weight of tetraethoxysilane was added.

### Synthesis Example 26

A siloxane copolymer was synthesized in the same manner as in Synthesis Example 1, except that a mixed solution of 15 parts by weight of vinyl trimethoxysilane, 15 parts by weight of 2-(3,4-epoxycyclohexyl)-ethyltrimethoxysilane, 35 parts by weight of phenyltrimethoxysilane, and 35 parts by weight of tetraethoxysilane was added.

### Synthesis Example 27

A siloxane copolymer was synthesized in the same manner as in Synthesis Example 1, except that a mixed solution of 15 parts by weight of vinyl trimethoxysilane, 16 parts by weight of 2-(3,4-epoxycyclohexyl)-ethyltrimethoxysilane, 35 parts by weight of phenyltrimethoxysilane, and 34 parts by weight of tetraethoxysilane was added.

### Synthesis Example 28

A siloxane copolymer was synthesized in the same manner as in Synthesis Example 1, except that a mixed solution of 15 parts by weight of vinyl trimethoxysilane, 20 parts by weight of 2-(3,4-epoxycyclohexyl)-ethyltrimethoxysilane, 35 parts by weight of phenyltrimethoxysilane, and 30 parts by weight of tetraethoxysilane was added.

### Synthesis Example 29

A siloxane copolymer was synthesized in the same manner as in Synthesis Example 1, except that a mixed solution of 15 parts by weight of vinyl trimethoxysilane, 30 parts by weight of 2-(3,4-epoxycyclohexyl)-ethyltrimethoxysilane, 35 parts by weight of phenyltrimethoxysilane, and 20 parts by weight of tetraethoxysilane was added.

### Synthesis Example 30

A siloxane copolymer was synthesized in the same manner as in Synthesis Example 1, except that a mixed solution of 15 parts by weight of 3-methylacryloxypropyl trimethoxysilane, 1 parts by weight of 3-glycidyloxypropyl trimethoxysilane, 35 parts by weight of phenyltrimethoxysilane, and 49 parts by weight of tetraethoxysilane was added.

### Synthesis Example 31

A siloxane copolymer was synthesized in the same manner as in Synthesis Example 1, except that a mixed solution of 15 parts by weight of 3-methylacryloxypropyl trimethoxysilane, 5 parts by weight of 3-glycidyloxypropyl trimethoxysilane, 35 parts by weight of phenyltrimethoxysilane, and 45 parts by weight of tetraethoxysilane was added.

### Synthesis Example 32

A siloxane copolymer was synthesized in the same manner as in Synthesis Example 1, except that a mixed solution of 15 parts by weight of 3-methylacryloxypropyl trimethoxysilane, 15 parts by weight of 3-glycidyloxypropyl trimethoxysilane, 35 parts by weight of phenyltrimethoxysilane, and 35 parts by weight of tetraethoxysilane was added.

### Synthesis Example 33

A siloxane copolymer was synthesized in the same manner as in Synthesis Example 1, except that a mixed solution of 15 parts by weight of 3-methylacryloxypropyl trimethoxysilane, 16 parts by weight of 3-glycidyloxypropyl trimethoxysilane, 35 parts by weight of phenyltrimethoxysilane, and 34 parts by weight of tetraethoxysilane was added.

### Synthesis Example 34

A siloxane copolymer was synthesized in the same manner as in Synthesis Example 1, except that a mixed solution of 15 parts by weight of 3-methylacryloxypropyl trimethoxysilane, 20 parts by weight of 3-glycidyloxypropyl trimethoxysilane, 35 parts by weight of phenyltrimethoxysilane, and 30 parts by weight of tetraethoxysilane was added.

### Synthesis Example 35

A siloxane copolymer was synthesized in the same manner as in Synthesis Example 1, except that a mixed solution of 15 parts by weight of 3-methylacryloxypropyl trimethoxysilane, 30 parts by weight of 3-glycidyloxypropyl trimethoxysilane, 35 parts by weight of phenyltrimethoxysilane, and 20 parts by weight of tetraethoxysilane was added.

### Synthesis Example 36

A siloxane copolymer was synthesized in the same manner as in Synthesis Example 1, except that 15 parts by weight of 3-methylacryloxypropyl trimethoxysilane, 1 part by weight of 2-(3,4-epoxycyclohexyl)-ethyltrimethoxysilane, 35 parts by weight of phenyltrimethoxysilane, and 49 parts by weight of tetraethoxysilane were added.

### Synthesis Example 37

A siloxane copolymer was synthesized in the same manner as in Synthesis Example 1, except that 15 parts by weight of 3-methylacryloxypropyl trimethoxysilane, 5 parts by weight of 2-(3,4-epoxycyclohexyl)-ethyltrimethoxysilane, 35 parts by weight of phenyltrimethoxysilane, and 45 parts by weight of tetraethoxysilane were added.

### Synthesis Example 38

A siloxane copolymer was synthesized in the same manner as in Synthesis Example 1, except that 15 parts by weight of 3-methylacryloxypropyl trimethoxysilane, 10 parts by weight of 2-(3,4-epoxycyclohexyl)-ethyltrimethoxysilane, 35 parts by weight of phenyltrimethoxysilane, and 40 parts by weight of tetraethoxysilane were added.

### Synthesis Example 39

A siloxane copolymer was synthesized in the same manner as in Synthesis Example 1, except that 15 parts by weight of 3-methylacryloxypropyl trimethoxysilane, 15 parts by weight of 2-(3,4-epoxycyclohexyl)-ethyltrimethoxysilane, 35 parts by weight of phenyltrimethoxysilane, and 35 parts by weight of tetraethoxysilane were added.

### Synthesis Example 40

A siloxane copolymer was synthesized in the same manner as in Synthesis Example 1, except that 15 parts by weight of 3-methylacryloxypropyl trimethoxysilane, 16 parts by weight of 2-(3,4-epoxycyclohexyl)-ethyltrimethoxysilane, 35 parts by weight of phenyltrimethoxysilane, and 34 parts by weight of tetraethoxysilane were added.

### Synthesis Example 41

A siloxane copolymer was synthesized in the same manner as in Synthesis Example 1, except that 15 parts by weight of 3-methylacryloxypropyl trimethoxysilane, 20 parts by weight of 2-(3,4-epoxycyclohexyl)-ethyltrimethoxysilane, 35 parts by weight of phenyltrimethoxysilane, and 30 parts by weight of tetraethoxysilane were added.

### Synthesis Example 42

A siloxane copolymer was synthesized in the same manner as in Synthesis Example 1, except that 15 parts by weight of 3-methylacryloxypropyl trimethoxysilane, 30 parts by weight of 2-(3,4-epoxycyclohexyl)-ethyltrimethoxysilane, 35 parts by weight of phenyltrimethoxysilane, and 20 parts by weight of tetraethoxysilane were added.

### Synthesis Example 43

A siloxane copolymer was synthesized in the same manner as in Synthesis Example 1, except that a mixed solution of 31 parts by weight of vinyl trimethoxysilane, 10 parts by weight of 3-glycidyloxypropyl trimethoxysilane, 35 parts by weight of phenyltrimethoxysilane, and 24 parts by weight of tetraethoxysilane was added.

### Synthesis Example 44

A siloxane copolymer was synthesized in the same manner as in Synthesis Example 1, except that a mixed solution of 35 parts by weight of vinyl trimethoxysilane, 10 parts by weight of 3-glycidyloxypropyl trimethoxysilane, 35 parts by weight of phenyltrimethoxysilane, and 20 parts by weight of tetraethoxysilane was added.

### Synthesis Example 45

A siloxane copolymer was synthesized in the same manner as in Synthesis Example 1, except that a mixed solution of 40 parts by weight of vinyl trimethoxysilane, 10 parts by weight of 3-glycidyloxypropyl trimethoxysilane, 35 parts by weight of phenyltrimethoxysilane, and 15 parts by weight of tetraethoxysilane was added.

### Synthesis Example 46

A siloxane copolymer was synthesized in the same manner as in Synthesis Example 1, except that a mixed solution of 15 parts by weight of vinyl trimethoxysilane, 31 parts by weight of 3-glycidyloxypropyl trimethoxysilane, 35 parts by weight of phenyltrimethoxysilane, and 19 parts by weight of tetraethoxysilane was added.

### Synthesis Example 47

A siloxane copolymer was synthesized in the same manner as in Synthesis Example 1, except that a mixed solution of 15 parts by weight of vinyl trimethoxysilane, 35 parts by weight of 3-glycidyloxypropyl trimethoxysilane, 35 parts by weight of phenyltrimethoxysilane, and 15 parts by weight of tetraethoxysilane was added.

### Synthesis Example 48

A siloxane copolymer was synthesized in the same manner as in Synthesis Example 1, except that a mixed solution of 15 parts by weight of vinyl trimethoxysilane, 40 parts by weight of 3-glycidyloxypropyl trimethoxysilane, 35 parts by weight of phenyltrimethoxysilane, and 10 parts by weight of tetraethoxysilane was added.

### Synthesis Example 49

A siloxane copolymer was synthesized in the same manner as in Synthesis Example 1, except that a mixed solution of 31 parts by weight of 3-methylacryloxypropyl trimethoxysilane, 10 parts by weight of 3-glycidyloxypropyl trimethoxysilane, 35 parts by weight of phenyltrimethoxysilane, and 24 parts by weight of tetraethoxysilane was added.

### Synthesis Example 50

A siloxane copolymer was synthesized in the same manner as in Synthesis Example 1, except that a mixed solution of 35 parts by weight of 3-methylacryloxypropyl trimethoxysilane, 10 parts by weight of 3-glycidyloxypropyl trimethoxysilane, 35 parts by weight of phenyltrimethoxysilane, and 20 parts by weight of tetraethoxysilane was added.

### Synthesis Example 51

A siloxane copolymer was synthesized in the same manner as in Synthesis Example 1, except that a mixed solution of 40 parts by weight of 3-methylacryloxypropyl trimethoxysilane, 10 parts by weight of 3-glycidyloxypropyl trimethoxysilane, 35 parts by weight of phenyltrimethoxysilane, and 15 parts by weight of tetraethoxysilane was added.

### Synthesis Example 52

A siloxane copolymer was synthesized in the same manner as in Synthesis Example 1, except that a mixed solution of 15 parts by weight of 3-methylacryloxypropyl trimethoxysilane, 31 parts by weight of 3-glycidyloxypropyl trimethoxysilane, 35 parts by weight of phenyltrimethoxysilane, and 19 parts by weight of tetraethoxysilane was added.

### Synthesis Example 53

A siloxane copolymer was synthesized in the same manner as in Synthesis Example 1, except that a mixed solution of 15 parts by weight of 3-methylacryloxypropyl trimethoxysilane, 35 parts by weight of 3-glycidyloxypropyl trimethoxysilane, 35 parts by weight of phenyltrimethoxysilane, and 15 parts by weight of tetraethoxysilane was added.

### Synthesis Example 54

A siloxane copolymer was synthesized in the same manner as in Synthesis Example 1, except that a mixed solution of 15 parts by weight of 3-methylacryloxypropyl trimethoxysilane, 40 parts by weight of 3-glycidyloxypropyl trimethoxysilane, 35 parts by weight of phenyltrimethoxysilane, and 10 parts by weight of tetraethoxysilane was added.

### Synthesis Example 55

A siloxane copolymer was synthesized in the same manner as in Synthesis Example 1, except that a mixed solution of 15 parts by weight of vinyl trimethoxysilane, 31 parts by weight of 2-(3,4-epoxycyclohexyl)-ethyltrimethoxysilane, 35 parts by weight of phenyltrimethoxysilane, and 34 parts by weight of tetraethoxysilane was added.

### Synthesis Example 56

A siloxane copolymer was synthesized in the same manner as in Synthesis Example 1, except that a mixed solution of 15 parts by weight of vinyl trimethoxysilane, 35 parts by weight of 2-(3,4-epoxycyclohexyl)-ethyltrimethoxysilane, 35 parts by weight of phenyltrimethoxysilane, and 30 parts by weight of tetraethoxysilane was added.

### Synthesis Example 57

A siloxane copolymer was synthesized in the same manner as in Synthesis Example 1, except that a mixed solution of 15 parts by weight of vinyl trimethoxysilane, 40 parts by weight of 2-(3,4-epoxycyclohexyl)-ethyltrimethoxysilane, 35 parts by weight of phenyltrimethoxysilane, and 25 parts by weight of tetraethoxysilane was added.

### Synthesis Example 58

A siloxane copolymer was synthesized in the same manner as in Synthesis Example 1, except that 35 parts by weight of phenyltrimethoxysilane and 65 parts by weight of tetra ethoxysilane excluding vinylsilane and epoxysilane were added in Synthesis Example 1.

### Synthesis Example 59

A siloxane copolymer was synthesized in the same manner as in Synthesis Example 1, except that a mixed solution of 35 parts by weight of phenyltrimethoxysilane and 50 parts by weight of tetraethoxysilane excluding 15 parts by weight of vinyl trimethoxysilane and epoxysilane were added in Synthesis Example 1.

### Synthesis Example 60

A siloxane copolymer was synthesized in the same manner as in Synthesis Example 1, except that 15 parts by weight of 3-methylacryloxypropyl trimethoxysilane and 50 parts by weight of tetraethoxysilane excluding 15 parts by weight of 3-methylacryloxypropyl trimethoxysilane and epoxysilane were added to the mixture solution.

### Synthesis Example 61

A siloxane copolymer was synthesized in the same manner as in Synthesis Example 1, except that 10 parts by weight of 3-glycidyloxypropyl trimethoxysilane, 35 parts by weight of phenyltrimethoxysilane, and 55 parts by weight of tetraethoxysilane excluding vinylsilane were added in Synthesis Example 1.

### Synthesis Example 62

A siloxane copolymer was synthesized in the same manner as in Synthesis Example 1, except that a mixed solution of 2-(3,4-epoxycyclohexyl)-ethyltrimethoxysilane, 35 parts by weight of phenyltrimethoxysilane, and 55 parts by weight of tetraethoxysilane excluding vinylsilane were added in Synthesis Example 1.

The solid content concentration of the siloxane copolymer of Synthesis Examples 1 to 62 is 20% to 40% by weight, and the Synthesis Examples are shown in Tables 1 to 3 below.

TABLE 1

| | | 3- | | | | |
|---|---|---|---|---|---|---|
| | | methylacryl | 3- | 2-(3,4- | | |
| | Vinyl | oxypropyl | glycidyloxypropyl | epoxycyclohexyl) | phenyl | |
| | trimethoxy | trimethoxy | trimethoxy | ethyl | tree | tetra |
| | silane | silane | silane | trimethoxysilane | methoxysilane | ethoxysilane |
| Synthesis | 1% | 0% | 10% | 0% | 35% | 54% |
| Example 1 | | | | | | |
| Synthesis | 4% | 0% | 10% | 0% | 35% | 51% |
| Example 2 | | | | | | |
| Synthesis | 5% | 0% | 10% | 0% | 35% | 50% |
| Example 3 | | | | | | |
| Synthesis | 10% | 0% | 10% | 0% | 35% | 45% |
| Example 4 | | | | | | |
| Synthesis | 15% | 0% | 10% | 0% | 35% | 40% |
| Example 5 | | | | | | |
| Synthesis | 20% | 0% | 10% | 0% | 35% | 35% |
| Example 6 | | | | | | |
| Synthesis | 21% | 0% | 10% | 0% | 35% | 34% |
| Example 7 | | | | | | |
| Synthesis | 30% | 0% | 10% | 0% | 35% | 25% |
| Example 8 | | | | | | |
| Synthesis | 0% | 1% | 10% | 0% | 35% | 54% |
| Example 9 | | | | | | |
| Synthesis | 0% | 4% | 10% | 0% | 35% | 51% |
| Example 10 | | | | | | |
| Synthesis | 0% | 5% | 10% | 0% | 35% | 50% |
| Example 11 | | | | | | |
| Synthesis | 0% | 10% | 10% | 0% | 35% | 45% |
| Example 12 | | | | | | |
| Synthesis | 0% | 15% | 10% | 0% | 35% | 40% |
| Example 13 | | | | | | |
| Synthesis | 0% | 20% | 10% | 0% | 35% | 35% |
| Example 14 | | | | | | |
| Synthesis | 0% | 21% | 10% | 0% | 35% | 34% |
| Example 15 | | | | | | |
| Synthesis | 0% | 30% | 10% | 0% | 35% | 25% |
| Example 16 | | | | | | |
| Synthesis | 15% | 0% | 1% | 0% | 35% | 49% |
| Example 17 | | | | | | |
| Synthesis | 15% | 0% | 5% | 0% | 35% | 45% |
| Example 18 | | | | | | |
| Synthesis | 15% | 0% | 15% | 0% | 35% | 35% |
| Example 19 | | | | | | |
| Synthesis | 15% | 0% | 16% | 0% | 35% | 34% |
| Example 20 | | | | | | |
| Synthesis | 15% | 0% | 20% | 0% | 35% | 30% |
| Example 21 | | | | | | |
| Synthesis | 15% | 0% | 30% | 0% | 35% | 20% |
| Example 22 | | | | | | |
| Synthesis | 15% | 0% | 0% | 1% | 35% | 49% |
| Example 23 | | | | | | |
| Synthesis | 15% | 0% | 0% | 5% | 35% | 45% |
| Example 24 | | | | | | |
| Synthesis | 15% | 0% | 0% | 10% | 35% | 40% |
| Example 25 | | | | | | |
| Synthesis | 15% | 0% | 0% | 15% | 35% | 35% |
| Example 26 | | | | | | |
| Synthesis | 15% | 0% | 0% | 16% | 35% | 34% |
| Example 27 | | | | | | |
| Synthesis | 15% | 0% | 0% | 20% | 35% | 30% |
| Example 28 | | | | | | |
| Synthesis | 15% | 0% | 0% | 30% | 35% | 20% |
| Example 29 | | | | | | |
| Synthesis | 0% | 15% | 1% | 0% | 35% | 49% |
| Example 30 | | | | | | |
| Synthesis | 0% | 15% | 5% | 0% | 35% | 45% |
| Example 31 | | | | | | |
| Synthesis | 0% | 15% | 15% | 0% | 35% | 35% |
| Example 32 | | | | | | |
| Synthesis | 0% | 15% | 16% | 0% | 35% | 34% |
| Example 33 | | | | | | |
| Synthesis | 0% | 15% | 20% | 0% | 35% | 30% |
| Example 34 | | | | | | |
| Synthesis | 0% | 15% | 30% | 0% | 35% | 20% |
| Example 35 | | | | | | |
| Synthesis | 0% | 15% | 0% | 1% | 35% | 49% |
| Example 36 | | | | | | |
| Synthesis | 0% | 15% | 0% | 5% | 35% | 45% |
| Example 37 | | | | | | |
| Synthesis | 0% | 15% | 0% | 10% | 35% | 40% |
| Example 38 | | | | | | |
| Synthesis | 0% | 15% | 0% | 15% | 35% | 35% |
| Example 39 | | | | | | |
| Synthesis | 0% | 15% | 0% | 16% | 35% | 34% |
| Example 40 | | | | | | |
| Synthesis | 0% | 15% | 0% | 20% | 35% | 30% |
| Example 41 | | | | | | |
| Synthesis | 0% | 15% | 0% | 30% | 35% | 20% |
| Example 42 | | | | | | |

Unit: % by weight

TABLE 2

| | | 3- | | | | |
|---|---|---|---|---|---|---|
| | | methylacryl | 3- | 2-(3,4- | | |
| | Vinyl | oxypropyl | glycidyloxypropyl | epoxycyclohexyl) | phenyl | |
| | trimethoxy | trimethoxy | trimethoxy | ethyl | tree | tetra |
| | silane | silane | silane | trimethoxysilane | methoxysilane | ethoxysilane |
| Synthesis | 31% | 0% | 10% | 0% | 35% | 24% |
| Example | | | | | | |
| 43 | | | | | | |
| Synthesis | 35% | 0% | 10% | 0% | 35% | 20% |
| Example | | | | | | |
| 44 | | | | | | |
| Synthesis | 40% | 0% | 10% | 0% | 35% | 15% |
| Example | | | | | | |
| 45 | | | | | | |
| Synthesis | 15% | 0% | 31% | 0% | 35% | 19% |
| Example | | | | | | |
| 46 | | | | | | |
| Synthesis | 15% | 0% | 35% | 0% | 35% | 15% |
| Example | | | | | | |
| 47 | | | | | | |
| Synthesis | 15% | 0% | 40% | 0% | 35% | 10% |
| Example | | | | | | |
| 48 | | | | | | |
| Synthesis | 0% | 31% | 10% | 0% | 35% | 24% |
| Example | | | | | | |
| 49 | | | | | | |
| Synthesis | 0% | 35% | 10% | 0% | 35% | 20% |
| Example | | | | | | |
| 50 | | | | | | |
| Synthesis | 0% | 40% | 10% | 0% | 35% | 15% |
| Example | | | | | | |
| 51 | | | | | | |
| Synthesis | 0% | 15% | 31% | 0% | 35% | 19% |
| Example | | | | | | |
| 52 | | | | | | |
| Synthesis | 0% | 15% | 35% | 0% | 35% | 15% |
| Example | | | | | | |
| 53 | | | | | | |
| Synthesis | 0% | 15% | 40% | 0% | 35% | 10% |
| Example | | | | | | |
| 54 | | | | | | |
| Synthesis | 15% | 0% | 0% | 31% | 35% | 34% |
| Example | | | | | | |
| 55 | | | | | | |
| Synthesis | 15% | 0% | 0% | 35% | 35% | 30% |
| Example | | | | | | |
| 56 | | | | | | |
| Synthesis | 15% | 0% | 0% | 40% | 35% | 25% |
| Example | | | | | | |
| 57 | | | | | | |

Unit: % by weight

TABLE 3

| | | 3- | | | | |
|---|---|---|---|---|---|---|
| | | methylacryl | 3- | 2-(3,4- | | |
| | Vinyl | oxypropyl | glycidyloxypropyl | epoxycyclohexyl) | | |
| | trimethoxy | trimethoxy | trimethoxy | ethyl | phenyl tree | tetra |
| | silane | silane | silane | trimethoxysilane | methoxysilane | ethoxysilane |
| Synthesis | 0% | 0% | 0% | 0% | 35% | 65% |
| Example | | | | | | |
| 58 | | | | | | |
| Synthesis | 15% | 0% | 0% | 0% | 35% | 50% |
| Example | | | | | | |
| 59 | | | | | | |
| Synthesis | 0% | 15% | 0% | 0% | 35% | 50% |
| Example | | | | | | |
| 60 | | | | | | |
| Synthesis | 0% | 0% | 10% | 0% | 35% | 55% |
| Example | | | | | | |
| 61 | | | | | | |
| Synthesis | 0% | 0% | 0% | 10% | 35% | 55% |
| Example | | | | | | |
| 62 | | | | | | |

### PREPARATION EXAMPLE

### Preparation of Photosensitive Resin Composition

### Example 1

10 parts by weight of 2-(O-benzoyloxime)-1-[4-(phenylthio)phenyl]-1,2-octanedione as a radical photoinitiator, phenyl (4-methoxyphenyl) iodonium hexafluoride as an ionic photoinitiator, 10 parts by weight of a 10-functional urethane acrylate oligomer, 20 parts by weight of dipentaerythritol hexaacrylate as a multifunctional monomer having an ethylenically unsaturated bond, 3 parts by weight of hexamethylolmelamine hexamethyl ether as a melamine crosslinking agent, and 2 parts by weight of (3-glycidoxypropyl)methyldiethoxysilane as a silane coupling agent were mixed with 100 parts by weight of the solid content of the siloxane copolymer solution prepared in Synthesis Example 1. Propylene glycol monoethyl acetate was added and dissolved to the mixture so that the solid content concentration was 20% by weight and then filtered through a 0.2 μm Millipore filter to prepare a photosensitive resin composition coating solution.

### Example 2

A photosensitive resin composition was prepared in the same manner as in Example 1, except that the copolymer of Synthesis Example 2 was applied in Example 1.

### Example 3

A photosensitive resin composition was prepared in the same manner as in Example 1, except that the copolymer of Synthesis Example 3 was applied in Example 1.

### Example 4

A photosensitive resin composition was prepared in the same manner as in Example 1, except that the copolymer of Synthesis Example 4 was applied in Example 1.

### Example 5

A photosensitive resin composition was prepared in the same manner as in Example 1, except that the copolymer of Synthesis Example 5 was applied in Example 1.

### Example 6

A photosensitive resin composition was prepared in the same manner as in Example 1, except that the copolymer of Synthesis Example 6 was applied in Example 1.

### Example 7

A photosensitive resin composition was prepared in the same manner as in Example 1, except that the copolymer of Synthesis Example 7 was applied in Example 1.

### Example 8

A photosensitive resin composition was prepared in the same manner as in Example 1, except that the copolymer of Synthesis Example 8 was applied in Example 1.

### Example 9

A photosensitive resin composition was prepared in the same manner as in Example 1, except that the copolymer of Synthesis Example 9 was applied in Example 1.

### Example 10

A photosensitive resin composition was prepared in the same manner as in Example 1, except that the copolymer of Synthesis Example 10 was applied in Example 1.

### Example 11

A photosensitive resin composition was prepared in the same manner as in Example 1, except that the copolymer of Synthesis Example 11 was applied in Example 1.

### Example 12

A photosensitive resin composition was prepared in the same manner as in Example 1, except that the copolymer of Synthesis Example 12 was applied in Example 1.

### Example 13

A photosensitive resin composition was prepared in the same manner as in Example 1, except that the copolymer of Synthesis Example 13 was applied in Example 1.

### Example 14

A photosensitive resin composition was prepared in the same manner as in Example 1, except that the copolymer of Synthesis Example 14 was applied in Example 1.

### Example 15

A photosensitive resin composition was prepared in the same manner as in Example 1, except that the copolymer of Synthesis Example 15 was applied in Example 1.

### Example 16

A photosensitive resin composition was prepared in the same manner as in Example 1, except that the copolymer of Synthesis Example 16 was applied in Example 1.

### Example 17

A photosensitive resin composition was prepared in the same manner as in Example 1, except that the copolymer of Synthesis Example 17 was applied in Example 1.

### Example 18

A photosensitive resin composition was prepared in the same manner as in Example 1, except that the copolymer of Synthesis Example 18 was applied in Example 1.

### Example 19

A photosensitive resin composition was prepared in the same manner as in Example 1, except that the copolymer of Synthesis Example 19 was applied in Example 1.

### Example 20

A photosensitive resin composition was prepared in the same manner as in Example 1, except that the copolymer of Synthesis Example 20 was applied in Example 1.

### Example 21

A photosensitive resin composition was prepared in the same manner as in Example 1, except that the copolymer of Synthesis Example 21 was applied in Example 1.

### Example 22

A photosensitive resin composition was prepared in the same manner as in Example 1, except that the copolymer of Synthesis Example 22 was applied in Example 1.

### Example 23

A photosensitive resin composition was prepared in the same manner as in Example 1, except that the copolymer of Synthesis Example 23 was applied in Example 1.

### Example 24

A photosensitive resin composition was prepared in the same manner as in Example 1, except that the copolymer of Synthesis Example 24 was applied in Example 1.

### Example 25

A photosensitive resin composition was prepared in the same manner as in Example 1, except that the copolymer of Synthesis Example 25 was applied in Example 1.

### Example 26

A photosensitive resin composition was prepared in the same manner as in Example 1, except that the copolymer of Synthesis Example 26 was applied in Example 1.

### Example 27

A photosensitive resin composition was prepared in the same manner as in Example 1, except that the copolymer of Synthesis Example 27 was applied in Example 1.

### Example 28

A photosensitive resin composition was prepared in the same manner as in Example 1, except that the copolymer of Synthesis Example 28 was applied in Example 1.

### Example 29

A photosensitive resin composition was prepared in the same manner as in Example 1, except that the copolymer of Synthesis Example 29 was applied in Example 1.

### Example 30

A photosensitive resin composition was prepared in the same manner as in Example 1, except that the copolymer of Synthesis Example 30 was applied in Example 1.

### Example 31

A photosensitive resin composition was prepared in the same manner as in Example 1, except that the copolymer of Synthesis Example 31 was applied in Example 1.

### Example 32

A photosensitive resin composition was prepared in the same manner as in Example 1, except that the copolymer of Synthesis Example 32 was applied in Example 1.

### Example 33

A photosensitive resin composition was prepared in the same manner as in Example 1, except that the copolymer of Synthesis Example 33 was applied in Example 1.

### Example 34

A photosensitive resin composition was prepared in the same manner as in Example 1, except that the copolymer of Synthesis Example 34 was applied in Example 1.

### Example 35

A photosensitive resin composition was prepared in the same manner as in Example 1, except that the copolymer of Synthesis Example 35 was applied in Example 1.

### Example 36

A photosensitive resin composition was prepared in the same manner as in Example 1, except that the copolymer of Synthesis Example 36 was applied in Example 1.

### Example 37

A photosensitive resin composition was prepared in the same manner as in Example 1, except that the copolymer of Synthesis Example 37 was applied in Example 1.

### Example 38

A photosensitive resin composition was prepared in the same manner as in Example 1, except that the copolymer of Synthesis Example 38 was applied in Example 1.

### Example 39

A photosensitive resin composition was prepared in the same manner as in Example 1, except that the copolymer of Synthesis Example 39 was applied in Example 1.

### Example 40

A photosensitive resin composition was prepared in the same manner as in Example 1, except that the copolymer of Synthesis Example 40 was applied in Example 1.

### Example 41

A photosensitive resin composition was prepared in the same manner as in Example 1, except that the copolymer of Synthesis Example 41 was applied in Example 1.

### Example 42

A photosensitive resin composition was prepared in the same manner as in Example 1, except that the copolymer of Synthesis Example 42 was applied in Example 1.

### Example 43

A photosensitive resin composition was prepared in the same manner as in Example 1, except that the copolymer of Synthesis Example 43 was applied in Example 1.

### Example 44

A photosensitive resin composition was prepared in the same manner as in Example 1, except that the copolymer of Synthesis Example 44 was applied in Example 1.

### Example 45

A photosensitive resin composition was prepared in the same manner as in Example 1, except that the copolymer of Synthesis Example 45 was applied in Example 1.

### Example 46

A photosensitive resin composition was prepared in the same manner as in Example 1, except that the copolymer of Synthesis Example 46 was applied in Example 1.

### Example 47

A photosensitive resin composition was prepared in the same manner as in Example 1, except that the copolymer of Synthesis Example 47 was applied in Example 1.

### Example 48

A photosensitive resin composition was prepared in the same manner as in Example 1, except that the copolymer of Synthesis Example 48 was applied in Example 1.

### Example 49

A photosensitive resin composition was prepared in the same manner as in Example 1, except that the copolymer of Synthesis Example 49 was applied in Example 1.

### Example 50

A photosensitive resin composition was prepared in the same manner as in Example 1, except that the copolymer of Synthesis Example 50 was applied in Example 1.

### Example 51

A photosensitive resin composition was prepared in the same manner as in Example 1, except that the copolymer of Synthesis Example 51 was applied in Example 1.

### Example 52

A photosensitive resin composition was prepared in the same manner as in Example 1, except that the copolymer of Synthesis Example 52 was applied in Example 1.

### Example 53

A photosensitive resin composition was prepared in the same manner as in Example 1, except that the copolymer of Synthesis Example 53 was applied in Example 1.

### Example 54

A photosensitive resin composition was prepared in the same manner as in Example 1, except that the copolymer of Synthesis Example 54 was applied in Example 1.

### Example 55

A photosensitive resin composition was prepared in the same manner as in Example 1, except that the copolymer of Synthesis Example 55 was applied in Example 1.

### Example 56

A photosensitive resin composition was prepared in the same manner as in Example 1, except that the copolymer of Synthesis Example 56 was applied in Example 1.

### Example 57

A photosensitive resin composition was prepared in the same manner as in Example 1, except that the copolymer of Synthesis Example 57 was applied in Example 1.

### Example 58

10 parts by weight of 2-(O-benzoyloxime)-1-[4-(phenylthio)phenyl]-1,2-octanedione as a radical photoinitiator, 10 parts by weight of phenyl (4-methoxyphenyl) iodonium hexafluoride as an ionic photoinitiator, 5 parts by weight of trifunctional trimethylolpropane triacrylate as a multifunctional monomer having an ethylenically unsaturated bond, 25 parts by weight of pentaerythritol hexaacrylate, 3 parts by weight of hexamethylolmelamine hexamethyl ether as a melamine crosslinking agent, 2 parts by weight of (3-glycidoxypropyl)methyldiethoxysilane as a silane coupling agent were mixed with 100 parts by weight of the solid content of the siloxane copolymer solution prepared in Synthesis Example 1. Propylene glycol monoethyl acetate was added and dissolved to the mixture so that the solid content concentration was 20% by weight and then filtered through a 0.2 μm Millipore filter to prepare a photosensitive resin composition coating solution.

### Example 59

A photosensitive resin composition was prepared in the same manner as in Example 58, except that 9 parts by weight of tri-functional trimethylolpropane triacrylate and 21 parts by weight of 6-functional dipentaerythritol hexaacrylate were used as the multifunctional monomer having an ethylenically unsaturated bond.

### Example 60

A photosensitive resin composition was prepared in the same manner as in Example 58, except that 12 parts by weight of tri-functional trimethylolpropane triacrylate and 18 parts by weight of 6-functional dipentaerythritol hexaacrylate were used as the multifunctional monomer having an ethylenically unsaturated bond.

### Example 61

A photosensitive resin composition was prepared in the same manner as in Example 58, except that 15 parts by weight of tri-functional trimethylolpropane triacrylate and 15 parts by weight of 6-functional dipentaerythritol hexaacrylate were used as the multifunctional monomer having an ethylenically unsaturated bond.

### Comparative Example 1

A photosensitive resin composition was prepared in the same manner as in Example 1, except that the copolymer of Synthesis Example 58 was applied in Example 1.

### Comparative Example 2

A photosensitive resin composition was prepared in the same manner as in Comparative Example 1, except that the copolymer of Synthesis Example 59 was applied in Comparative Example 1.

### Comparative Example 3

A photosensitive resin composition was prepared in the same manner as in Comparative Example 1, except that the copolymer of Synthesis Example 60 was applied in Comparative Example 1.

### Comparative Example 4

A photosensitive resin composition was prepared in the same manner as in Comparative Example 1, except that the copolymer of Synthesis Example 61 was applied in Comparative Example 1.

### Comparative Example 5

A photosensitive resin composition was prepared in the same manner as in Comparative Example 1, except that the copolymer of Synthesis Example 62 was applied in Comparative Example 1.

After evaluating the physical properties in the following manner using the photosensitive resin composition coating solutions prepared in Examples 1 to 61 and Comparative Examples 1 to 5, the results are shown in Tables 4 to 6 below.

A) Synthetic reproducibility: when the synthesis was carried out with the same composition 5 times, when the change in weight average molecular weight was 1,000 g/mol or less, it was denoted by ◯, when the change in weight average molecular weight was greater than 1,000 and less than or equal to 2,000 g/mol, it was denoted by Δ, and when the change in weight average molecular weight was 2,000 g/mol or more, it was denoted by ×.

The weight average molecular weight is a polystyrene-converted molecular weight measured using Gel Permeation Chromatography (GPC).

B) Adhesion: the negative photosensitive composition solutions prepared in Examples 1 to 61 and Comparative Examples 1 to 5 were coated on a glass substrate on which SiNx was deposited using a spin coater and then prebaked on a hot plate at 80° C. for 2 minutes to form a 2.0 μm film. The film obtained above was irradiated with ultraviolet rays having an intensity of 10 mW/cm² at 365 nm using a predetermined pattern mask using a broadband exposure machine for 5 seconds. Thereafter, development was performed at 23° C. for 60 seconds with an aqueous solution of 2.38% by weight of tetramethyl ammonium hydroxide, followed by washing with ultrapure water for 60 seconds. For final curing, a patterned film was obtained by heating in an oven at 85° C. for 60 minutes. 2, 4, 6, 8, 10, 20, 50, and 100 μm Line & Space were measured through an Olympus microscope. If there was no peel-off, it was denoted by ◯, if there was peeling at 6 μm or less, it was denoted as Δ, and if there was peeling at 8 μm or more, it was denoted as ×.

C) Residual film rate: the residual film rate of sensitivity at which the residual film rate is saturated during the measurement of the adhesive force of (B) above was confirmed. At this time, if the residual film ratio was 75% or more, it was denoted by ◯, if it was more than 70% and less than 75%, it was denoted by Δ, and if it was 70% or less, it was denoted by ×.

D) Residue: the residue (Scum) was inspected based on the contact hole of the pattern film formed during the measurement of the adhesive force of (B) above. A case in which no residue was observed at this time was denoted by ◯, a case in which the residue was observed only in the outer shell part of the pattern, it was denoted by Δ, and a case in which the residue was observed in both the external shell part and the center part was denoted by ×.

E) Chemical resistance: the pattern (Pattern) film formed during the sensitivity measurement of (a) above was placed in a stripper at 60° C. for 120 seconds and left to stand, and then the adhesive force was measured. At this time, the case where there was no abnormality in the film was denoted by ◯, the case where there was damage to the film was denoted by Δ, and the case where peel-off occurred was denoted by ×.

TABLE 4

| | Synthetic | | | | |
|---|---|---|---|---|---|
| | reproduci- | | Residual | | Chemical |
| | bility | Adhesion | film rate | Residue | resistance |
| Example 1 | ◯ | ◯ | ◯ | ◯ | ◯ |
| Example 2 | ◯ | ◯ | ◯ | ◯ | ◯ |
| Example 3 | ◯ | ◯ | ◯ | ◯ | ◯ |
| Example 4 | ◯ | ◯ | ◯ | ◯ | ◯ |
| Example 5 | ◯ | ◯ | ◯ | ◯ | ◯ |
| Example 6 | ◯ | ◯ | ◯ | ◯ | ◯ |
| Example 7 | ◯ | ◯ | ◯ | ◯ | ◯ |
| Example 8 | ◯ | ◯ | ◯ | ◯ | ◯ |
| Example 9 | ◯ | ◯ | ◯ | ◯ | ◯ |
| Example 10 | ◯ | ◯ | ◯ | ◯ | ◯ |
| Example 11 | ◯ | ◯ | ◯ | ◯ | ◯ |
| Example 12 | ◯ | ◯ | ◯ | ◯ | ◯ |
| Example 13 | ◯ | ◯ | ◯ | ◯ | ◯ |
| Example 14 | ◯ | ◯ | ◯ | ◯ | ◯ |
| Example 15 | ◯ | ◯ | ◯ | ◯ | ◯ |
| Example 16 | ◯ | ◯ | ◯ | ◯ | ◯ |
| Example 17 | ◯ | ◯ | ◯ | ◯ | ◯ |
| Example 18 | ◯ | ◯ | ◯ | ◯ | ◯ |
| Example 19 | ◯ | ◯ | ◯ | ◯ | ◯ |
| Example 20 | ◯ | ◯ | ◯ | ◯ | ◯ |
| Example 21 | ◯ | ◯ | ◯ | ◯ | ◯ |
| Example 22 | ◯ | ◯ | ◯ | ◯ | ◯ |
| Example 23 | ◯ | ◯ | ◯ | ◯ | ◯ |
| Example 24 | ◯ | ◯ | ◯ | ◯ | ◯ |
| Example 25 | ◯ | ◯ | ◯ | ◯ | ◯ |
| Example 26 | ◯ | ◯ | ◯ | ◯ | ◯ |
| Example 27 | ◯ | ◯ | ◯ | ◯ | ◯ |
| Example 28 | ◯ | ◯ | ◯ | ◯ | ◯ |
| Example 29 | ◯ | ◯ | ◯ | ◯ | ◯ |
| Example 30 | ◯ | ◯ | ◯ | ◯ | ◯ |
| Example 31 | ◯ | ◯ | ◯ | ◯ | ◯ |
| Example 32 | ◯ | ◯ | ◯ | ◯ | ◯ |
| Example 33 | ◯ | ◯ | ◯ | ◯ | ◯ |
| Example 34 | ◯ | ◯ | ◯ | ◯ | ◯ |
| Example 35 | ◯ | ◯ | ◯ | ◯ | ◯ |
| Example 36 | ◯ | ◯ | ◯ | ◯ | ◯ |
| Example 37 | ◯ | ◯ | ◯ | ◯ | ◯ |
| Example 38 | ◯ | ◯ | ◯ | ◯ | ◯ |
| Example 39 | ◯ | ◯ | ◯ | ◯ | ◯ |
| Example 40 | ◯ | ◯ | ◯ | ◯ | ◯ |
| Example 41 | ◯ | ◯ | ◯ | ◯ | ◯ |
| Example 42 | ◯ | ◯ | ◯ | ◯ | ◯ |

TABLE 5

| | Synthesis | | | | |
|---|---|---|---|---|---|
| | Reproduci- | | Residual | | Chemical |
| | bility | Adhesion | film rate | Residue | resistance |
| Example 43 | ◯ | ◯ | ◯ | Δ | ◯ |
| Example 44 | Δ | ◯ | ◯ | Δ | ◯ |
| Example 45 | Δ | ◯ | ◯ | Δ | ◯ |
| Example 46 | Δ | ◯ | ◯ | ◯ | ◯ |
| Example 47 | Δ | ◯ | ◯ | ◯ | ◯ |
| Example 48 | Δ | ◯ | ◯ | ◯ | ◯ |
| Example 49 | ◯ | ◯ | ◯ | Δ | ◯ |
| Example 50 | Δ | ◯ | ◯ | Δ | ◯ |
| Example 51 | Δ | ◯ | ◯ | Δ | ◯ |
| Example 52 | Δ | ◯ | ◯ | ◯ | ◯ |
| Example 53 | Δ | ◯ | ◯ | ◯ | ◯ |
| Example 54 | Δ | ◯ | ◯ | ◯ | ◯ |
| Example 55 | Δ | ◯ | ◯ | ◯ | Δ |
| Example 56 | Δ | ◯ | ◯ | ◯ | Δ |
| Example 57 | Δ | ◯ | ◯ | ◯ | Δ |
| Example 58 | ◯ | ◯ | ◯ | ◯ | ◯ |
| Example 59 | ◯ | ◯ | ◯ | ◯ | ◯ |
| Example 60 | ◯ | ◯ | ◯ | ◯ | ◯ |
| Example 61 | ◯ | ◯ | ◯ | ◯ | ◯ |

TABLE 6

| | Synthesis | | | | |
|---|---|---|---|---|---|
| | Reproduci- | | Residual | | Chemical |
| | bility | Adhesion | film rate | Residue | resistance |
| Comparative | ◯ | X | X | X | X |
| Example 1 | | | | | |
| Comparative | ◯ | X | ◯ | X | ◯ |
| Example 2 | | | | | |
| Comparative | ◯ | X | ◯ | X | ◯ |
| Example 3 | | | | | |
| Comparative | ◯ | ◯ | Δ | ◯ | X |
| Example 4 | | | | | |
| Comparative | ◯ | ◯ | Δ | ◯ | X |
| Example 5 | | | | | |

Through the above Tables 4 to 6, it was seen that the adhesion, residual film rate, residue, and chemical resistance of the photosensitive resin composition prepared according to the present disclosure were superior to those of Comparative Examples 1 to 5. In particular, when copolymerized at a specific ratio of Examples 1 to 42, it was seen that the synthetic reproducibility, adhesive force, residual film rate, residue, and chemical resistance were all greatly excellent.

Although embodiments of the present disclosure have been described in detail above, it will be apparent to those skilled in the art that the scope of the present disclosure is not limited thereto, and various modifications may be made without departing from the technical idea of the present disclosure.

What is claimed is:

1. A photosensitive resin composition comprising:
a siloxane copolymer comprising a thermosetting functional group and a photocurable functional group;
a photoinitiator; and
a solvent.

2. The composition of claim 1, wherein the thermosetting functional group has a structure comprising at least one selected from an epoxy group, oxetane, and tetrahydrofuran (THF).

3. The composition of claim 1, wherein the photocurable functional group has a structure comprising an unsaturated photocurable functional group.

4. The composition of claim 1, wherein the photocurable functional group has a structure comprising at least one functional group selected from a vinyl group and an acrylate group.

5. The composition of claim 1, wherein the photoinitiator is included in an amount of 0.1 to 30 parts by weight with respect to 100 parts by weight of the siloxane copolymer.

6. The composition of claim 1, wherein the photoinitiator comprises a radical photoinitiator and an ionic photoinitiator.

7. The composition of claim 6, wherein the radical photoinitiator is included in an amount of 0.1 to 20 parts by weight and the ionic photoinitiator is included in an amount of 0.1 to 10 parts by weight, with respect to 100 parts by weight of the siloxane copolymer.

8. The composition of claim 1, wherein the siloxane copolymer comprises repeating units respectively represented by Formula 1 and 2: 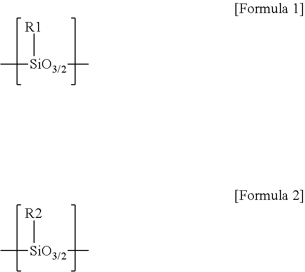
wherein R1 is the thermosetting functional group, and R2 is the photocurable functional group.

9. The composition of claim 8, wherein in the siloxane copolymer, each of the repeating units respectively represented by Formula 1 and 2 is included in an amount of 1 mol % to 30 mol %.

10. The composition of claim 1, wherein the siloxane copolymer has average molecular weight of 3,000 to 30,000 g/mol which is a polystyrene-converted weight.

11. The composition of claim 8, wherein the siloxane copolymer further comprises a repeating unit represented by Formula 3: 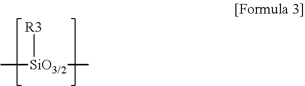
where R3 is any one selected from a hydroxyl group, a phenyl group, and an alkyl group having 1 to 10 carbon atoms.

12. The composition of claim 11, wherein the siloxane copolymer comprises 1 mol % to 30 mol % of the repeating unit represented by Formula 1, 1 mol % to 30 mol % of the repeating unit represented by Formula 2, and 50 mol % to 90 mol % of the repeating unit represented by Formula 3.

13. The composition of claim 1, wherein the photosensitive resin composition further comprises a polyfunctional monomer or oligomer having an ethylenically unsaturated bond.

14. The composition of claim 13, wherein the composition comprises 1 to 50 parts by weight of the multifunctional monomer or oligomer having an ethylenically unsaturated bond with respect to 100 parts by weight of the siloxane copolymer.

15. The composition of claim 14, wherein the multifunctional monomer or oligomer has 2 to 20 functional groups.

16. The composition of claim 14, wherein the multifunctional oligomers comprise one or more oligomers selected from the group consisting of aliphatic urethane acrylate oligomers, aromatic urethane acrylate oligomers, epoxy acrylate oligomers, epoxy methacrylate oligomers, polyester acrylate oligomers, silicone acrylate oligomers, melamine acrylate oligomers, and dendritic acrylate oligomers.

17. The composition of claim 14, wherein the multifunctional monomer comprises: a first monomer that is a di-, tri-, tetra-, or penta-functional group; and a second monomer that is a hexa- or higher-functional group.

18. The composition of claim 17, wherein a molar ratio of the first monomer to the second monomer is 3:7 to 4:6.

19. The composition of claim 1, wherein the solvent is at least one selected from the group consisting of methyl-2-hydroxyisobutyrate, ethylene glycol methyl ether acetate, 2-methoxy-1-methylethyl ester, propylene acetate, ethyl propionate, ethyl pyruvate, 1-methoxy-2-propanol, dibutyl ether, ethylene glycol monomethyl ether, ethylene glycol dimethyl ether, propylene glycol dimethyl ether, tetrahydrofuran, methanol, ethanol, and isopropyl alcohol.

20. A display device comprising a cured body of the photosensitive resin composition of claim 1.
